(19) United States
(12) Patent Application Publication
(10) Pub. No.: US 2012/0230530 A1
(43) Pub. Date: Sep. 13, 2012

(54) PASSENGER SERVICE UNIT, PASSENGER SERVICE CHANNEL AND MEANS OF TRANSPORT

(75) Inventor: Dirk-Achim SCHEVARDO, Rothenbach (DE)

(73) Assignee: DIEHL AEROSPACE GMBH, Uberlingen (DE)

(21) Appl. No.: 13/396,005

(22) Filed: Feb. 14, 2012

(30) Foreign Application Priority Data
Mar. 8, 2011 (DE) 10 2011 013 368.2

(51) Int. Cl. H04R 1/02; H05K 7/02

(52) U.S. Cl. 381/333; 361/748

(57) ABSTRACT

The invention relates in particular to a passenger service unit 1 for aircraft cabins. The passenger service unit 1 comprises a plurality of service functions implemented on the basis of functional electronic units. The functional electronic units are accommodated without cabling on a common circuit board 3.

### BACKGROUND OF THE INVENTION

The invention relates to a passenger service unit, to a passenger service channel and to means of transport equipped therewith.

### DISCUSSION OF THE PRIOR ART

Passenger service units are found, for example in passenger aircraft above the rows of seats and are used to provide various service functions for the passengers. The service functions provided are conventionally reading lights, loudspeakers and one or more illuminable symbols, for example a no-smoking symbol or a fasten seatbelt symbol.

Such a passenger service unit is known, for example, from DE 10 2009 032 078. In particular, a method for simplifying the installation outlay for a passenger service channel is also proposed therein. Despite the already known method, however, there is a further need for simplification of the installation and mounting of passenger service units and passenger service channels.

### SUMMARY OF THE INVENTION

On the basis of this, it is an object of the invention to provide a passenger service unit and a passenger service channel for a means of transport, which can be mounted and installed in a simple fashion.

This object is achieved by the independent claims. Advantageous refinements may be found in the respective dependent claims.

In particular, in order to achieve this object according to a first independent claim, a passenger service unit for cabins of means of transport is proposed, in particular for aircraft cabins, which comprises a plurality of service functions implemented on the basis of functional electronic units.

Here, the wording “on the basis of functional electronic units” is intended to mean in particular that the service functions are achieved or provided at least partially by functions or the cooperation of electronic units, in particular electronic components and electronic circuits. For example in the case of a symbol which, by illumination, requests the passenger to wear their seatbelt by optical highlighting, an illumination light source optionally with an associated electronic circuit or controller forms the functional electronic unit on which it is based,

In the passenger service unit, which will be referred below to as a “service unit” for brevity, the functional electronic units are accommodated without cabling on a preferably common circuit board.

The term “without cabling” is intended in particular to mean that the functional electronic units do not have or require additional cables or cabling routed outside the circuit board. In the cabling-free configuration, a conductor arrangement for example for electricity supply and/or signal transmission relating to the functional electronic units is implemented by means of conductor tracks on the circuit board and, if applicable, optionally via cableless connections, for example radio and the like. A cable connection may be provided merely for connecting the circuit board to an on-board electrical system, whether for electrical energy supply or data transmission, although it does not have to be. It should, however, be pointed out that such a cable connection does not relate directly to the functional electronic units of the circuit board, so that the term cabling-free can still be used.

The mounting and installation outlay can be greatly reduced with the proposed service unit, in particular because cabling of the functional units is not required. Furthermore precisely because cabling of the functional units is not required, a weight advantage can be achieved compared with elaborately cabled service units as in the prior art. The latter is an important factor particularly in the aviation industry. In addition, manufacturing and mounting costs can be reduced. Furthermore, a longer lifetime can be achieved since cable breaks, contact problems etc. can be avoided by the cabling-free configuration.

In particular, particularly effective reduction of the mounting and installation outlay can be achieved in a particularly preferred configuration by fitting all the functional electronic units on a single or common circuit board. In this case, only a single circuit board needs to be mounted, which may be done for example by means of a latch connection, and optionally connected to the on-board electrical system. Connection of the service unit to the on-board electrical system may be established, for example, by a plug connection. It is, however, also possible for the connection between the service unit and the on-board electrical system to be carried out at least partially via a wireless connection, in particular a radio connection.

At least one of the functional units is preferably selected from the following group: selection unit, illumination unit, display unit, acoustic unit, sensor unit, control unit.

A selection unit may, for example, offer one or more predetermined service functions to a passenger for selection. An illumination unit may, for example, comprise a reading light which can be switched on or off or dimmed by passenger actuation, for example by means of a selection unit, for example a switch or button. A display unit may, for example, be formed to display one or more in particular predetermined display symbols. The display symbols may in this case be represented as predetermined pictograms which can be highlighted by illumination or back-lighting, or by means of digital display modules. The acoustic unit may, for example, comprise a loudspeaker module for the output of various acoustic signals or spoken information or requests. The sensor unit may comprise one or more sensors by which parameters arid values specific in particular to the passenger space, seating space or reclining space can be acquired. On the basis and as a function of the acquired parameters or values, further functional units, for example illumination etc., may for example be operated and in particular controlled. The control unit may comprise one or more control modules or electronic control components, which may be formed to control, regulate or monitor one or more functional units.

The service unit preferably comprises functional units respectively for individual passenger standing spaces, seating spaces or reclining spaces. To this extent, it is advantageous for the service unit to be fitted in the vicinity of the respective standing, seating or reclining spaces and in each case to be easy to reach. In particular, the installation point on the lower side of overhead storage lockers above the rows of seats, which is conventional for commercial aircraft, may be envisaged.

As described above, a service unit may comprise a plurality or even a multiplicity of service functions. Owing to the cabling-free fitting of the functional electronic units on the circuit board, the service unit can still be mounted and installed comparatively easily even with a complex structure. With increasing complexity, furthermore, the fact of saving weight because cabling is not required is also a crucial advantage.

In one configuration, the selection unit may comprise at least one selection field fitted on the circuit board and/or at least one selection field which can be connected cablelessly to a selection interface fitted on the circuit board. The selection field may comprise at least one switching element which operates mechanically, touch-sensitively or touchlessly. The switching element may in this case comprise a mechanical switch or button by which a switching component arranged on the circuit board can be actuated, for example by means of a plunger and/or other mechanical coupling elements. The switching element may also comprise a switching component which can be actuated through capacitive or inductive processes by touching an icon. The actuation or touching of the icon by a passenger may also be transmitted by radio signals, or in another way cablelessly to the switching component. The latter is advantageous in particular when the icon is placed remotely from the circuit board, particularly in the case of a mobile user interface formed in the manner of a remote control. Cableless transmission may also be used when the icon is fitted on the passenger seat while the circuit board is arranged in the overhead region. Instead of or in addition to the described switching elements, the selection field may also comprise one or more touch- sensitive display fields, so-called touch displays, by which a selection and switching function can likewise be provided. With respect to transmitting the actuation of an icon on the display field to the switching component, the principles mentioned above apply accordingly.

In one configuration, the illumination unit may comprise at least one illumination light source fitted preferably in a fixed fashion on the circuit board. The illumination light source preferably comprises at least one luminescent light source, preferably at least one electroluminescent light source, in particular one or more LEDs (light-emitting diodes) and/or OLEDs (organic light-emitting diodes). The illumination light source may, for example, be a component of a reading light or other light for illuminating a certain spatial region in the vicinity of a passenger seating space, a passenger standing space or a passenger reclining space. Cabling can be obviated by fitting the illumination light source directly on the circuit board, so that the mounting of the service unit can be greatly simplified.

The illumination light source may comprise single- or multi-coloured light sources, in particular single- or multi-coloured LEDs and/or OLEDs. With a suitable configuration of the illumination unit, for example a corresponding controller for the light sources, mixed colours, including white light, can be generated by multi-coloured light sources. The mixed colours may in this case be adjusted so that illumination, in particular situation-adapted illumination, is achieved for the respective spatial region. The adjustment of a respective mixed colour may either be carried out automatically or predetermined. It is also possible for the respective passenger to be able to adjust the respectively desired mixed colour by means of the service unit. To this end the service unit, in particular the selection unit, may comprise corresponding switching elements, selection elements, sliders and the like. In particular the switching elements, selection elements etc. may be provided by a touch-sensitive display, with the aid of which the passenger can select the desired mixed colour. To this end, for example, a palette of possible colours, and optionally even the full possible colour space or a section thereof, may be provided for selection on the display.

In order to cool the illumination light source, in particular the light sources, particularly the LEDs and/or OLEDs, corresponding heat sinks may be provided and/or the circuit board per se may be used at least partially as a heat sink. To this end, the circuit board may for example comprise regions or elements which dissipate heat appropriately well, in particular comprising highly thermally conductive material such as copper, clad bores, passages or holes, in particular so-called vias,

In one configuration, the display unit comprises at least one display field fitted on the circuit board, a display field which can be connected cablelessly to a display interface arranged on the circuit board and/or at least one projection display field which can be illuminated or back-lit by a projection light source fitted on the circuit board. The display unit may, for example, be formed to display one or more symbols to a passenger, for example in the form of pictograms. The pictograms may be arranged on a surface through which light can shine, so that they, and the information associated with them, can be highlighted by illuminating the surface with the projection light source. Instead of a projection-based display, it is also possible to use other display units, for example digital display fields, displays etc.

In one configuration, the acoustic unit comprises at least one loudspeaker module fitted on the circuit board and/or at least one loudspeaker module which can be connected cablelessly to a loudspeaker interface arranged on the circuit board. The loudspeaker module may be used to play acoustic signals, warnings and/or announcements which are intended for a respective passenger or a group of passengers. As in the case of the other cablelessly configured functional units, comparatively simple mounting and installation can be achieved because of the cableless configuration of the acoustic unit.

In one configuration, the sensor unit may comprise at least one sensor module fitted on the circuit board and/or at least one sensor module which can be connected cablelessly to a sensor interface fitted on the circuit board, the sensor module or modules being in particular formed and adapted to acquire passenger-specific parameters. The acquired parameters may, in particular, be used by other functional units or for controlling other functional units. The parameters which may be envisaged are, in particular, the brightness in the region of a passenger seat, standing space or reclining space, the presence or absence of the passenger, the temperature, the position and/or arrangement of objects and items of equipment in the region of a passenger seat, standing space or reclining space etc. For the position and/or arrangement of objects and items of equipment, the backrest and armrest of a seat, folding tray of the respective seating space, seatbelt of the respective seating space etc. may in particular be envisaged. The respectively acquired parameters may be compared with predetermined reference values and, in the event of significant issues, countermeasures may be initiated. For example, a symbol indicating the issue may be displayed on the display unit as a countermeasure, for example a symbol to fasten the seatbelt, and/or the colour of the illumination may be adjusted to a respective signal colour. The countermeasure is preferably continued until the issue has been resolved, which may be done by comparing the respectively acquired parameters with the reference values continuously or at certain time intervals. The parameters, or the data acquired by the sensor unit, may at least partially also be forwarded to a central computer unit so that cabin crew can be made aware of them and optionally intervene. An issue may for example, at the start of a flight, consist in the backrest not being in an upright position and/or the folding table or the folding tray not being folded up and/or the seatbelt not being worn and fastened. The respective passenger is made aware of the issue by displaying a corresponding symbol. By forwarding to a central computer unit, for example a central cabin management system, the issues may also be brought to the attention of others, in particular the service crew. For the case of specific illumination of the respective passenger seat, standing space or reclining space, for example with the colour red, or any other signal colour, both the respective passenger and the service crew can easily identify the passenger seat, standing space or reclining space where there are issues. Particularly with appropriate illumination, the service crew can recognize issues essentially at a glance through the cabin. It is also possible, in the event that there are no issues, or no issues are established, for corresponding positive status displays or messages to be produced, in particular with corresponding symbols and/or corresponding illumination.

In an advantageous configuration, the service unit further comprises at least one optical unit respectively having at least one optical element preferably fitted in a fixed fashion. The term optical unit is in this case also intended to cover in particular one or more optical elements formed for the purpose of deviating and/or focusing or diverging light. An optical unit may accordingly comprise one or more lenses, in particular a lens system having a plurality of lenses, and/or other optical elements such as mirrors, collimators, reflectors etc.

For aircraft cabins with seat groups of 3, for example, a lens system having two lenses will be considered sufficient.

The optical unit is placed after at least one of the illumination light sources and is formed and adapted so that light emerging from the illumination light source can be directed onto a predetermined illumination region in the cabin. There are, in particular, the options that an optical unit is provided respectively for an illumination light source or simultaneously for a plurality of illumination light sources.

The lenses, or more generally the optical elements, are preferably arranged behind one another and mutually offset. In such cases, deviation of the illumination light sources arranged in a fixed fashion on the circuit board into the respectively desired direction can be carried out effectively and with a comparatively small installation space.

Optical units may be used in connection with the illumination light sources, particularly in reading lights for passenger seats. For passenger seats whose installation position remains fixed, so that the region respectively to be illuminated is likewise predetermined, the optical units and the position of the optical units relative to the respective illumination light source may be predetermined. By suitable configuration of the optical units, particularly in connection with high-power light sources, for instance high-power light-emitting diodes, a separate adjustment facility for adapting the emission characteristic and the emission cone is no longer absolutely necessary. In particular, this offers design simplifications. The surfaces which the light generated e.g. by the reading lights strikes can also be configured more simply compared with the situation with adjustment facilities, which is advantageous particularly with a view to the design options and easy cleaning of the respective surfaces.

However, it is quite within the scope of the invention to furthermore provide an adjustment device for modification, in particular manual modification, preferably automatic modification, of the position and/or alignment of the at least one optical element in such a way that the illumination region and/or the illumination in the respective illumination region can be adapted. Such an adjustment device may, for example, be coupled to a corresponding function of the selection unit so that the optical unit can be adjusted according to the respective selection. That is to say, options for adjusting the optical unit could be provided by means of the selection unit. It would furthermore be possible for setting of the optical unit to be carried out automatically with the aid of the sensor data of the sensor unit, at least within certain limits.

The optical unit may, for example, be fastened on the circuit board or the illumination light source. Preferably, however, the optical unit is fitted on a cover carrying the circuit board. In the latter case, it is possible to use the same circuit board design, or more precisely a circuit board with predetermined configuration, geometry and applied components, for a multiplicity of different covers, which may possibly be necessary for different geometries, positions and sizes of the regions to be illuminated. In particular, an appropriate arrangement of the optical units and the optical elements on the cover may achieve the effect that the light emitted by the illumination light sources arranged on the circuit board is deviated and/or focused in a respectively appropriate fashion. In this way, the illumination unit can be adapted in a straightforward and flexible fashion to different geometries, sizes and positions of the regions to be illuminated, which may for example depend on the arrangement, spacing and size of passenger seats, while keeping the same circuit board design.

The optical unit can be formed in a particularly space-saving and compact fashion. For example, the optical unit may have a length of about 30 mm or less, preferably about 25 mm or less, preferably about 20 mm or less. It is furthermore possible that a light exit face of the illumination unit, preferably with position and orientation set in a fixed fashion, for example placed on the cover, has length and/or width dimensions of about 18 mm or more. Such geometries have proven sufficient in particular for reading lights at passenger seats in aircraft cabins. The light exit face may in this case be formed in a rectangular, square, round, oval, triangular fashion etc. For round light exit faces, there is a preferred diameter of about 18 mm or more.

According to another configuration, the illumination light source is formed so that its brightness, luminous intensity, luminous flux, colour, spectrum and/or spatial emission characteristic can be varied, preferably as a function of parameters determined by the sensor unit and/or selected or input via the selection unit.

The service unit may, as already indicated, furthermore comprise a cover which is placed on the cabin side for its designated use and fitted in front of the circuit board. It is particularly preferable for the circuit board to be connected releasably, preferably by means of a latch connection, to the cover. This allows on the one hand simple installation and simple mounting, and on the other hand comparatively easy replacement of the circuit board.

In one configuration, the cover comprises fastening structures for fastening the selection field, the display field, the loudspeaker module, the sensor module and/or the optical unit, in particular the lens system, the fastening structures being formed and adapted in such a way that the respective fields or modules—if necessary—are automatically connected to corresponding interfaces of the circuit board when the circuit board is mounted on the cover,

A second independent claim provides a passenger service channel, comprising at least one passenger service unit according to at least one configuration of the preceding description which can be fitted on it, preferably releasably, and is preferably freely positionable in the longitudinal direction of the passenger service channel.

According to one configuration of the passenger service channel, it may be formed and adapted so that an on-board electrical system interface of the circuit board is automatically connected to a corresponding on-board electrical system interface of the means of transport when the passenger service unit or the circuit board is mounted on the passenger service channel.

For further advantages and advantageous effects of the passenger service channel, reference is made to the comments above, which apply accordingly.

Yet another independent claim provides a means of transport comprising at least one passenger service unit according to at least one configuration as described above and/or at least one passenger service channel according to at least one configuration as described above. With respect to the advantages, reference is made to the comments above.

### BRIEF DESCRIPTION OF THE DRAWINGS

Exemplary embodiments of the invention will, be described in more detail below with the aid of the appended drawings, in which:

FIG. 1 shows a rear view of a service unit;

FIG. 2 shows a front view of a service unit;

FIG. 3 schematically shows a detail of the service unit;

FIG. 4 schematically shows a cross section of the service unit; and

FIG. 5 schematically shows a further detail of the service unit,

### DETAILED DESCRIPTION OF THE INVENTION

Throughout the figures, elements which are the same or functionally equivalent are provided with the same references. The figures are not necessarily true to scale, and scales may vary between the figures.

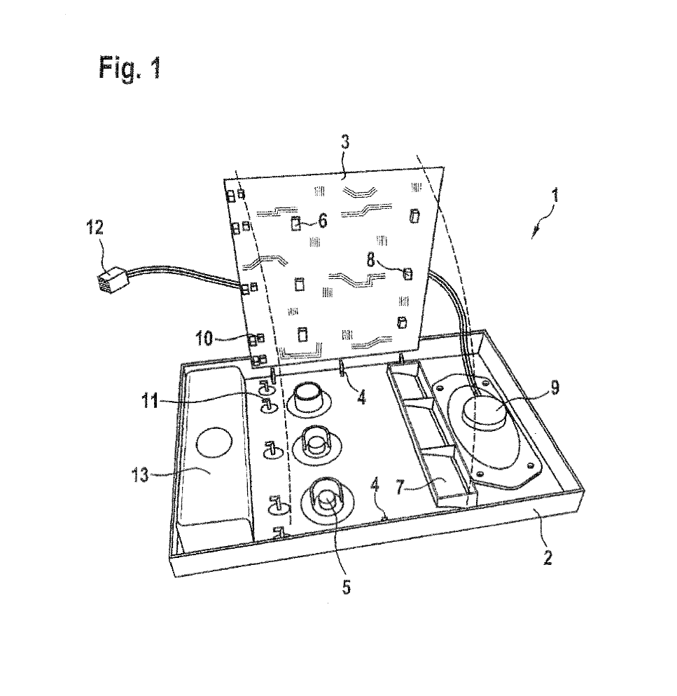

FIG. 1 shows a rear view of a service unit 1 of an aircraft cabin. A rear view is intended to mean the view of the side of the service unit which faces away during conventional use in the aircraft cabin.

The service unit 1 comprises a cover 2 and a circuit board 3. The cover 2 is fitted in front of the circuit board 3 on the cabin side for designated use and mounting of the service unit 1. The circuit board 3 is connected releasably to the cover 2 by means of latch elements 4.

By the service unit 1, a passenger can be provided with a plurality of service functions based on functional electronic units. In the example shown, the service unit 1 comprises reading lights, respectively comprising an optical unit 5 and an LED 6 fitted on the circuit board 3. The service unit 1 furthermore comprises a plurality of projection display fields 7, separated from one another by webs, for the representation or display of information, each projection display field 7 being assigned an LED 8 by which the projection display field 7 can be illuminated from behind in order to highlight the symbol located on it. The symbols may by way of example be indications to wear the seatbelt, or prohibition signs relating to the use of mobile telephones or relating to smoking,

The service unit 1 furthermore comprises a loudspeaker 9 for the acoustic output of information. The loudspeaker 9 is a component of an acoustic unit, and the loudspeaker 9 can be connected to an acoustic module arranged on the circuit board by means of a cable or with corresponding contact elements, for example contact pins, which connect automatically during mounting. The use of automatically connecting contact elements has the advantage of reduced cabling outlay and concomitant weight savings.

The service unit 1 furthermore comprises a plurality of buttons, each comprising a switching element 10 arranged on the circuit board 3 and a switching knob 11 fitted in a mobile fashion on the cover 2. The switching knob 11 is adapted arid formed so that, in the mounted state, actuation of the switching knob 11 carried out for example by a passenger is transmitted mechanically by means of a plunger onto the switching element 10. These are therefore buttons with mechanical actuation and activation. The button may, for example, be adapted to switch the reading light on and off, and as an emergency knob for notifying the cabin crew or for other selection and switching purposes.

It should be noted that the number of components respectively comprised by the service unit 1 may also differ from the number shown in the figures. For instance, more or fewer buttons, reading lights etc. may be provided.

The circuit board 3 comprises a plurality of functional electronic units, for example having one or more electronic components, accommodated on it, each of which functional electronic units is assigned to at least one service function of the service unit 1. The implementation of the functional units on a common circuit board 3 permits a cabling-free structure of the service unit 1. Merely the connection of the circuit board 3 to an on-board electrical system of the aircraft may be configured using a cable connection 12, although in this case it is also possible to use cabling-free plug connections which are connected automatically when the service unit 1 is installed. Contactless connections are also possible, in particular connections based on radio or optical signal transmission between the circuit board, or more precisely the functional electronic units, and the on-board electrical system.

For the sake of completeness and without entering into further details, the service unit 1 furthermore comprises a ventilation unit 13 with fresh air nozzles 14 on the cabin side (Fig.

It is clear that the mounting and installation outlay for the service unit can be reduced significantly by the cabling-free structure.

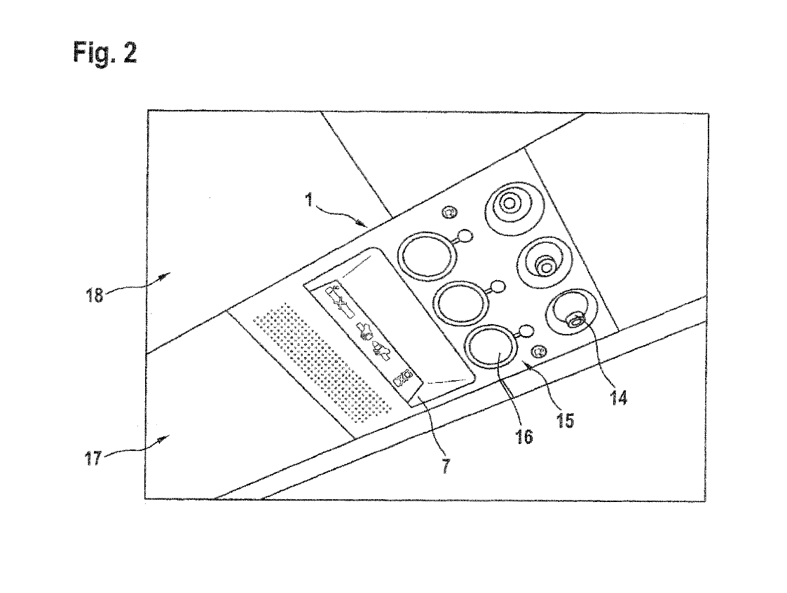

FIG. 2 shows a front view of a service unit 1. A front view in this context is intended to mean a cabin-side view of the service unit 1, i.e. a view which is available to a passenger located inside the aircraft cabin.

In the view of FIG. 2, the service unit 1 can be formally subdivided into five different segments.

A first segment relates to the fresh air nozzles 14, which will not be discussed in further detail since they generally neither comprise nor are connected to functional electronic units. It is, however, within the scope of the invention for the fresh air nozzles 14, and in a wider sense the fresh air supply, to be operated on the basis of a functional electronic unit, for example controlled or regulated by a functional electronic unit, possibly while taking sensor data into account. For example, it is possible for the air flow and/or the temperature of the emerging air to be selected or adjusted using a selection unit, and for the fresh air nozzles or the fresh air supply to be correspondingly adjusted automatically. In this case, for example, actuators or the like acting on the fresh air nozzles may be used,

In the example represented, a second segment comprises a total of five switching knobs 11. Two of the switching knobs 11, the outer ones in the representation, are provided as call buttons for the cabin crew. The other three switching knobs 11 are intended for switching on and off the reading lights 15, which form a third segment. The switching knobs 11 may be equipped with integrated illumination. For example, light from a light source on the circuit board 3, in particular an LED, may be guided via a light guide onto a transparent window of the switching knobs 11.

In the representation, the reading lights 15 comprise light exit elements 16 fitted on the cabin side of the cover 2 in a fixed fashion, in particular not rotatably and not tiltably. Light exit elements 16 formed in this way have the advantage that a continuous and easily cleanable surface can be produced for the cover 2.

The service unit 1 shown is formed for a triple seat group, i.e. a reading light 15 and a fresh air nozzle 14 are provided for each seat of the triple seat group. So that each of the seats can be illuminated in a suitable way, or suitably lit in the corresponding region, the optical units 5 are formed so that the light generated by the light sources on the circuit board 3 is correspondingly deviated and optionally concentrated and focused or, depending on the situation, even diverged. Further details of this will be found in the description below.

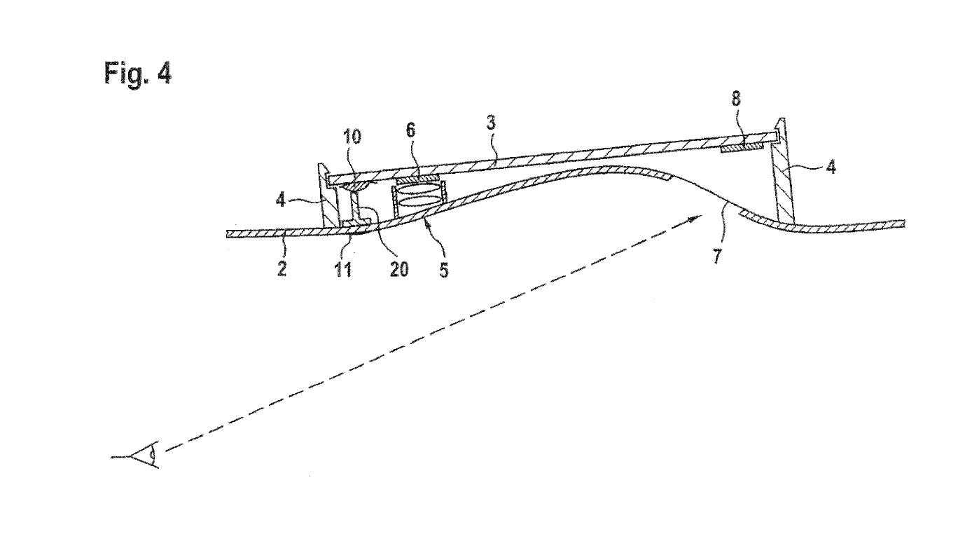

A fourth segment comprises the projection display fields 7, which are integrated on the cabin side in a unitary recess panel. The recess panel is adapted, here inclined, so that the symbols of the projection display fields 7 can be read easily from the passenger seat, which is indicated in FIG. 4 by the schematic human eye. Only one each of the projection display fields 7 is provided in the present case. It is, however, also possible for certain symbols to be provided specifically for seating spaces and optionally activatable specifically for seating spaces. Displaying the seat space number or the name of the passenger may, for example, be envisaged here. In order to display the name of the passenger, however, it is advantageous not to use projection display fields 7 but instead electronic display fields, for example 7-segment displays, which can display a wide variety of different information depending on the way in which they are operated,

In the example shown, the symbols can be seen even without back-lighting by the LEDs 8. By activating the back-lighting, i.e. the LEDs 8, the symbols are highlighted so that the passenger is made aware of the corresponding information. It would also be possible for the symbols to be invisible without back-lighting, so that the signalling action when activating the back-lighting could be reinforced.

A fifth segment comprises sound passage openings for the loudspeaker 9. Since these sound passage openings make it more difficult to clean the cover 2, it is also possible to use a continuous diaphragm or the like, through which sound can pass, in the region of the loudspeaker 9, or even to form the cover 2 itself, or at least a part thereof, as a system capable of oscillation, for example as a resonant body, by means of which sound can be emitted. It is, in particular, possible for an oscillator by means of which sound transmission can take place, in particular a so-called exciter, to be fitted on the circuit board or on the cover. The oscillators could correspondingly be acoustically coupled to the cover 2, for example adhesively bonded, so that sound emission can take place through the cover 2. An oscillator fitted on the cover, i.e. acoustically coupled to the cover 2, could be connected cablelessly to the circuit board by means of suitable contacts, in which case these contacts may be configured so that connection automatically takes place when the circuit board 3 is mounted on the cover 2.

FIG. 2 also shows the way in which the cover can be integrated in a passenger service channel 17 in the region below the overhead storage lockers 18.

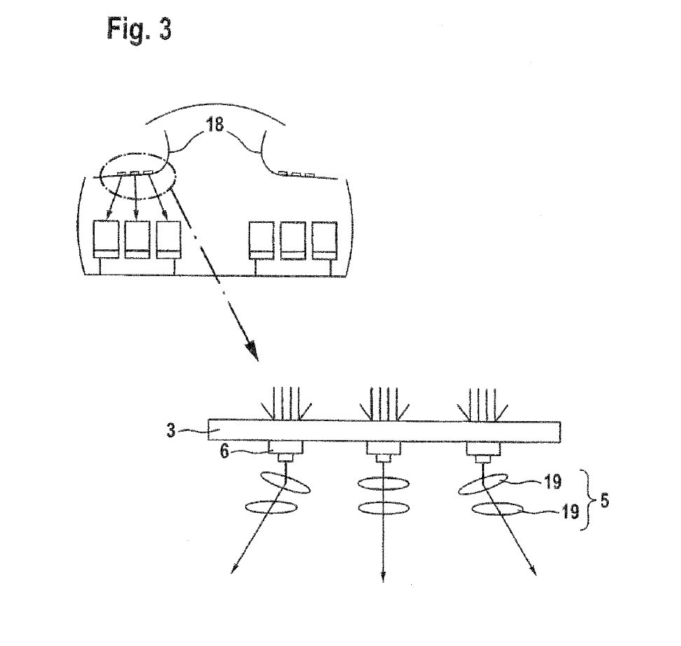

FIG. 3 shows a detail of the service unit 1; its relative position in the cabin and with respect to a triple seat group being revealed by the upper left representation in FIG. 3, showing a schematic cross section of the passenger cabin. The detail shown in FIG. 3, likewise represented in cross section, specifically relates to the illumination unit of the service unit 1, or more precisely the deviation and orientation by the optical unit 5 of the light generated by the LEDs 6. The LEDs 6 arranged on the circuit board 3 are not, and for reasons of space in the general case cannot be, arranged directly above the corresponding passenger seats. Therefore, for optimal lighting or illumination of the respectively desired regions of the passenger seats, it is necessary to deviate the light appropriately, which is indicated by arrows in FIG. 3. Deviation and optionally focusing or diverging of the light is advantageously carried out with the optical units 5. An optical unit 5 is respectively assigned to each of the LEDs 6.

Each optical unit 5 in the present case comprises two lenses 19 arranged in succession. The lenses 19 may be mutually tilted with respect to their optical axes and arranged mutually offset. The latter may, for example, be done in order to achieve suitable deviation, here transversely to the longitudinal direction of the aircraft, of the light emerging from the LEDs 6. An offset and tilting for the outer two optical units 5 can be seen in the representation of FIG. 3. The optical units 5 may, for example, have a length of 25 mm or less transversely to the circuit board plane, in which case the light exit face for light, for example the light exit face of the light exit elements 16, may for example have a diameter of 18 mm or more.

FIG. 4 schematically shows a cross section of the service unit 1. In particular, FIG. 4 reveals the relative position and orientation of the individual elements, in particular the LEDs 6, the associated optical units 5, the switching knobs 11 and the switching elements 10, the LEDs 8 and the projection display field 7. The fastening of the circuit board 3 on the cover 2 by means of latch elements can furthermore be seen clearly.

With respect to the switching knobs 11, it should again be mentioned that they comprise plungers 20 which act on the switching elements 11 on the circuit board 3, and correspondingly actuate them, when the switching knobs 11 are actuated. In the case of illuminable switching knobs 11, light from an LED may be guided through these plungers 20, for example by means of light guides, to a transparent section of the passenger-side surface of the switching knobs 11.

As can likewise be seen from FIG. 4, the optical units 5, or more precisely the lenses 19, are fastened on the cover 2. This has the advantage that the same circuit board 3, or more precisely the same circuit board design, particularly with respect to the lighting or illumination of the corresponding region of the passenger seat, can be used for different seat configurations and seat arrangements. For another seat configuration, without requiring modifications or adaptations of the circuit board 3, it is merely necessary for the arrangement and adaptation of the individual lenses 19 to be modified appropriately. The latter, however, usually does not present a difficult problem since different covers 2 are generally used in any case for different seat configurations, for example in different types of aircraft, so that the fastening elements for the lenses 19 can correspondingly be provided during their production.

It is however also possible to provide fastening elements, or rather fastening systems for the lenses, which allow different arrangements and orientations of the lenses 19. This case, the illumination of a service unit 1 can be modified without a new cover being required. This may be advantageous for example for the case of modifying the seat space distribution, for example when modifying the seat spacings in a row of seats. The adjustability of the lenses 19, and therefore of the optical units 5, may be implemented mechanically or by corresponding actuators and positioning motors.

Adjustability of the lenses 5 may in principle also be provided, so that individual adjustment of the illumination is possible for the respective passenger. To this end, the service unit may for example comprise further switching or selection elements with which the illumination, in particular the deviation and focusing of the light, can be modified. Further switching or selection elements, which may for example be a component of a selection unit, may be provided for modifying further parameters of the illumination, for example brightness and/or colour etc. The switching and selection elements, including those mentioned above, may be formed mechanically or touch-sensitively, particularly in the form of touch-sensitive displays.

It is also possible to adjust the illumination, in particular the orientation, brightness, colour etc. on the basis of data acquired by means of sensors, in particular passenger-specific and/or environment-specific data and/or data specific to the day or local time. To this end, the service unit 1 may comprise corresponding sensors; it is within the scope of the invention for data acquired by means of sensors to be used for automatic adjustment, adaptation and/or provision of other service functions. The acquired data may, at least partially, also be forwarded to a superordinate bus system which is connected to a central control computer, so that the function of the service unit 1, for example the number and scope of the respectively available service functions, can be set or controlled centrally. To this end, the bus system may in particular be formed as a two-way bus system which allows interchange of information from and to the service units 1. It is also possible for service units 1 to interchange information with one another, for example in order to compare acquired information and data and/or to check for validity or consistency. Furthermore, for example for a certain passenger region inside the cabin, functions, in particular function ranges, of the service units l may automatically be adapted to one another, in particular while taking respectively available parameters into account, by communication with the central control computer or by communication of the service units 1 with one another.

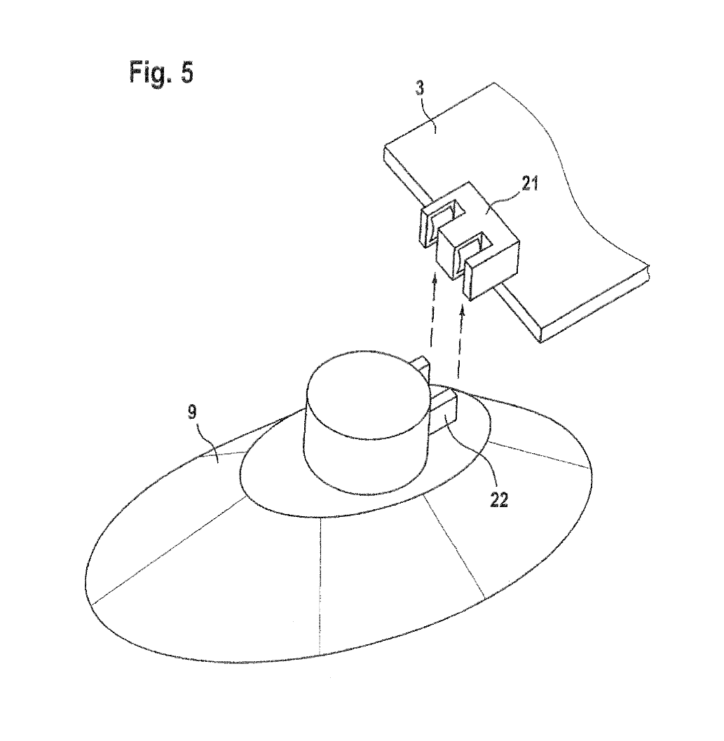

FIG. 5 schematically shows a further detail of the service unit 1. Specifically, FIG. 5 shows a way in which the loudspeaker 9 can be electrically connected to the circuit board 3 in a straightforward way, or more precisely to corresponding audio components on the circuit board 3. To this end, the circuit board 3 comprises a first interface 21, and the loudspeaker comprises a second interface 22. The first 21 and second interface 22 are formed, arranged and fitted so that the circuit board 3 is automatically electrically connected to the loudspeaker 9 when the circuit board 3 is mounted on the cover 2, which is carried out in the present case by means of latch elements 4. The electrical contact may, for example, be used for the transmission of audio signals,

It should expressly be pointed out that cableless or cabling-free connection by means of cableless interfaces, as described above, may be used in a similar way to connect further elements, in particular assigned to service functions of the service unit 1, electrically to the circuit board 3. In particular, it should be mentioned that the connection, described above, of the circuit board 3 to the on-board electrical system, carried out by means of a cable connection 12, may be configured as cabling-free connection by means of corresponding interfaces, as described above.

Particularly in conjunction with the description of the exemplary embodiments, it is clear that the proposed service unit allows simple mounting and installation together with weight reduction,

### List of References

1 service unit
2 cover
3 circuit board
4 latch element
5 optical unit
6 LED
7 projection display field
8 LED
9 loudspeaker
10 switching element
11 switching knob
12 cable connection
13 ventilation unit
14 fresh air nozzle
15 reading light
16 light exit element
17 passenger service channel
18 overhead storage locker
19 lens
20 plunger
21 first interface
22 second interface

What is claimed is:

1. Passenger service unit for cabins of means of transport, in particular for aircraft cabins, comprising a plurality of service functions implemented on the basis of functional electronic units, the functional electronic units being accommodated essentially without cabling on a common circuit board.

2. Passenger service unit according to claim 1, wherein at least one of the functional unit is selected from the group: selection unit, illumination unit, display unit, acoustic unit, sensor unit, control unit.

3. Passenger service unit according to claim 2, wherein the selection unit comprises at least one selection field fitted on the circuit board and/or at least one selection field which can be connected cablelessly to a selection interface fitted on the circuit board, the selection field comprising at least one switching element which operates mechanically, touch-sensitively and/or touchlessly.

4. Passenger service unit according to claim 2, wherein the illumination unit comprises at least one illumination light source fitted preferably in a fixed fashion on the circuit board.

5. Passenger service unit according to claim 4, wherein said illumination light source is a luminescent light source.

6. Passenger service unit according to claim 5, wherein said luminescent light source is an electroluminescent light source.

7. Passenger service unit according to claim 6, wherein said electroluminescent light source is an LED or OLED.

8. Passenger service unit according to claim 2, wherein the display unit comprises at least one display field fitted on the circuit board, a display field which can be connected cablelessly to a display interface arranged on the circuit board and/or at least one projection display field which can be back-lit by a projection light source fitted on the circuit board.

9. Passenger service unit according to claim 2, wherein the acoustic unit comprises at least one loudspeaker module fitted on the circuit board and/or at least one loudspeaker module which can be connected cablelessly to a loudspeaker interface arranged on the circuit board.

10. Passenger service unit according to claim 2, wherein the sensor unit comprises at least one sensor module fitted on the circuit board and/or at least one sensor module which can be connected cablelessly to a sensor interface fitted on the circuit board, the sensor module or modules being in particular formed and adapted to acquire passenger- and/or environment-specific parameters.

11. Passenger service unit according to claim 4, furthermore comprising at least one optical unit respectively having at least one optical element preferably fitted in a fixed fashion, the optical unit being placed after at least one of the illumination light sources and being formed and adapted so that light emerging from the illumination light source can be directed onto a predetermined illumination region in the cabin.

12. Passenger service unit according to claim 11, wherein the optical unit comprises a lens system comprising a plurality of lenses arranged mutually offset.

13. Passenger service unit according to claim 12, wherein said plurality of lenses comprises two lenses.

14. Passenger service unit according to claim 8, further comprising an adjustment device for modification, of the position and/or alignment of the at least one optical element in such a way that the illumination region and/or the illumination in the respective illumination region can be adapted.

15. Passenger service unit according to claim 14, wherein said adjustment device for modification is an adjustment device for automatic or manual modification.

16. Passenger service unit according claim 8, wherein the optical unit has a length of about 30 mm or less, and wherein a light exit face, preferably with position and orientation set in a fixed fashion, is provided for the illumination unit, the length and/or width dimension of which face is about 18 mm or more.

17. Passenger service unit according to claim 16, wherein the optical unit has a length of about 25 mm or less.

18. Passenger service unit according to claim 16, wherein the optical unit has a length of about 20 mm or less.

19. Passenger service unit according to claim 8, wherein the illumination light source is formed so that its brightness, luminous intensity, luminous flux, colour, spectrum and/or spatial emission characteristic can be varied as a function of parameters determined by the sensor unit and/or input via the selection unit.

20. Passenger service unit according to claim 19, wherein the brightness, luminous intensity, luminous flux, color, spectrum and/or spatial emission characteristic of the illumination light source is varied.

21. Passenger service unit according to claim 1, further comprising a cover which is placed on the cabin side for its designated use and fitted in front of the circuit board, to which the circuit board is connected preferably releasably, preferably by means of a latch connection.

22. Passenger service unit according to claim 21, wherein the cover comprises fastening structures for fastening the selection field, the display field, the loudspeaker module, the sensor module and/or the optical unit, in particular the lens system, in such a way that the respective fields or modules are automatically connected to corresponding interfaces of the circuit board when the circuit board is mounted on the cover.

23. Passenger service channel, comprising at least one passenger service unit according to claim 1, which is fitted on it, preferably releasably, and is freely positionable in the longitudinal direction of the passenger service channel, wherein the passenger service channel is formed and adapted so that an on-board electrical system interface of the circuit board is automatically connected to a corresponding on-board electrical system interface of the means of transport when the circuit board is mounted on the passenger service channel.

24. Means of transport, in particular aircraft, comprising at least one passenger service unit according to claim 1 and/or at least one passenger service channel comprising at least one passenger service unit according to claim 1, which is fitted on it, preferably releasably, and is freely positionable in the longitudinal direction of the passenger service channel, wherein the passenger service channel is formed and adapted so that an on-board electrical system interface of the circuit board is automatically connected to a corresponding on-board electrical system interface of the means of transport when the circuit board is mounted on the passenger service channel.
